(19) United States
(12) Patent Application Publication
(10) Pub. No.: US 2019/0190306 A1
(43) Pub. Date: Jun. 20, 2019

(54) SYSTEMS FOR AND METHODS OF TRANSPORTING ENERGY STORAGE SYSTEMS

(71) Applicant: FreeWire Technologies, Inc., San Leandro, CA (US)

(72) Inventors: Arcady SOSINOV, San Francisco, CA (US); Richard STEELE, San Leandro, CA (US); Carolin FUNK, Berkeley, CA (US)

(21) Appl. No.: 16/155,088

(22) Filed: Oct. 9, 2018

Related U.S. Application Data
(60) Provisional application No. 62/570,089, filed on Oct. 9, 2017.

(51) Int. Cl. H02J 7/14; H01L 35/02; H02N 2/18; H02J 3/38; B62D 63/06; B60P 7/08

(52) U.S. Cl. CPC H02J 7/14; H01L 35/02; H02N 2/18; H02J 7/345; H02J 3/386; B62D 63/06; B60P 7/08; H02J 3/383

(57) ABSTRACT

One aspect of the present invention pertains to a method of transporting energy storage systems. Another aspect of the present invention pertains to a system for transporting energy storage systems.

### CROSS-REFERENCE TO RELATED APPLICATIONS

The present application claims benefit of U.S. Provisional Patent application Ser. No. 62/570,089, entitled “SYSTEMS FOR AND METHODS OF TRANSPORTING ENERGY STORAGE SYSTEMS,” to Arcady SOSINOV, Richard STEELE, and Carolin FUNK filed Oct. 9, 2017. The present application is related to U.S. Pat. No. 9,592,742; the content U.S. Pat. No. 9,592,742 is incorporated herein in its entirety by this reference for all purposes.

### BACKGROUND

The use of electrically powered equipment ranging from mobile electronic devices, to power tools, to electric vehicles and many more is expected to grow. A variety of options and technologies exist that may solve one or more expected challenges that may result from the desire to use electric power. The present inventors have developed one or more solutions that may address one or more problems related to providing access to energy storage systems for electric power sources.

### SUMMARY

One aspect of the present invention pertains to transport systems which may be used to transport energy storage systems. Another aspect of the present invention pertains to a method of charging energy storage systems.

It is to be understood that the invention is not limited in its application to the details of construction and to the arrangements of the components set forth in the following description. The invention is capable of other embodiments and of being practiced and carried out in various ways. In addition, it is to be understood that the phraseology and terminology employed herein are for the purpose of description and should not be regarded as limiting.

### BRIEF DESCRIPTION OF THE DRAWINGS

FIG. 1 is a diagram of a transport system according to one or more embodiments of the present invention.

FIG. 1-1 is a diagram of a transport system according to one or more embodiments of the present invention.

FIG. 1-2 is a diagram of a transport system according to one or more embodiments of the present invention.

FIG. 2 is a diagram of a transport system according to one or more embodiments of the present invention.

FIG. 3 is a diagram of a transport system according to one or more embodiments of the present invention.

FIG. 4 a diagram of a transport system according to one or more embodiments of the present invention.

FIG. 5 is a diagram of a transport system according to one or more embodiments of the present invention.

FIG. 6 is a diagram of a transport system according to one or more embodiments of the present invention.

FIG. 7 is a a diagram of a transport system according to one or more embodiments of the present invention.

FIG. 8 is a diagram of a transport system according to one or more embodiments of the present invention.

Skilled artisans appreciate that elements in the figures are illustrated for simplicity and clarity and have not necessarily been drawn to scale. For example, the dimensions of some of the elements in the figures may be exaggerated relative to other elements to help to improve understanding embodiments of the present invention.

### DESCRIPTION

In the following description of the figures, identical reference numerals have been used when designating substantially identical elements or processes that are common to the figures.

Unless otherwise defined, all technical and scientific terms used herein have the same meaning as commonly understood by one of ordinary skill in the art to which this invention belongs. In case of conflict with publications, patent applications, patents, and other references mentioned incorporated herein by reference, the present specification, including definitions, will control.

Various embodiments of the present invention may include any of the described features, alone or in combination. Other features and/or benefits of this disclosure will be apparent from the following description.

For the following defined terms, these definitions shall be applied, unless a different definition is given in the claims or elsewhere in this specification.

“Autonomous” is defined herein as meaning capable of operating without direct real-time control by a person(s) or operating without direct real-time control by a person(s).

“Drive battery” is defined herein as meaning a battery that provides power for propelling an electric vehicle.

“Electric vehicle” (EV) is defined herein as meaning a vehicle for which at least some of the energy for moving the vehicle is derived from an onboard stored electric power supply such as a battery and/or a capacitor. Examples of electric vehicles include, but are not limited to, a battery electric vehicle, a capacitor electric vehicle, a hybrid electric vehicle, and a plug-in hybrid electric vehicle.

“Mobile” is defined herein as meaning capable of moving and/or being moved as in not fixed to one position or place.

“Motorized” is defined herein as meaning capable of self-propulsion such as having a motor, an engine, or other drive mechanism to accomplish locomotion.

“Remote control” is defined herein as meaning operating or being controlled from a distance.

“Trailer” is defined herein as a vehicle having a frame, a housing, and/or a platform to support an item for transport wherein the transport is accomplished by towing the trailer with an automotive vehicle.

“Self driven” is defined herein as meaning driven by computer or mechanical system without real time human input such as without a human driver.

“Self propelled” is defined herein as meaning capable of independently generating forces to produce movement from one location to another location.

“Wireless” is defined herein as meaning not having a solid physical connection for conveying information, data, signals, and/or energy.

“Wired” is defined herein as meaning having a solid physical connection for conveying information, data, signals, and/or energy.

All numeric values are herein defined as being modified by the term “about,” whether or not explicitly indicated. The term “about” generally refers to a range of numbers that a person of ordinary skill in the art would consider equivalent to the stated value to produce substantially the same properties, function, result, etc. A numerical range indicated by a low value and a high value is defined to include all numbers subsumed within the numerical range and all subranges subsumed within the numerical range. As an example, the range 10 to 15 includes, but is not limited to, 10, 10.1, 10.47, 11, 11.75 to 12.2, 12.5, 13 to 13.8, 14, 14.025, and 15.

The order of execution or performance of the operations or the processes in embodiments of the invention illustrated and described herein is not essential, unless otherwise specified. That is, the operations or the processes may be performed in any order, unless otherwise specified, and embodiments of the invention may include additional or fewer operations or processes than those disclosed herein. For example, it is contemplated that executing or performing a particular operation or process before, simultaneously with, contemporaneously with, or after another operation or process is within the scope of aspects of the invention.

As will be understood by a person skilled in the art, aspects of the present invention may be embodied as a system, method, or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as an “apparatus”, a “circuit,” a “module” or a “system.” Furthermore, aspects of the present invention may take the form of a computer program product embodied in one or more non-transitory computer readable medium(s) having computer readable program code embodied, e.g., stored, thereon.

Any combination of one or more non-transitory computer readable mediums may be utilized. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Computer program code for carrying out operations for aspects of the present invention may be written in any combination of one or more programming languages, including an object oriented programming language such as Java™, Smalltalk, C++ or the like and conventional procedural programming languages, such as the “C” programming language, such as .net framework and Microsoft Corporation programming languages and databases, such as HTML5, Android Mobile applications and Apple Corporation iOS mobile applications, or similar programming languages. The program code may execute entirely on a local computer, partly on the local computer, as a stand-alone software package, partly on the local computer and partly on a remote computer, or entirely on the remote computer or server. In the latter scenario, the remote computer may be connected to the local computer through a network, or the connection may be made to an external computer (for example, through the Internet using an Internet Service Provider). The program code may reside on remote servers and software networks such as for cloud computing such as, but not limited to, Amazon Web Services, Google cloud etc.

Aspects of the present invention are described below with reference to flowchart illustrations and/or block diagrams of methods, processes, apparatus (systems), and/or computer program products according to embodiments of the invention. It is to be understood that each block of the flowchart illustrations and/or block diagrams, and combinations of blocks in the flowchart illustrations and/or block diagrams, may be implemented using computer program instructions. These computer program instructions may be provided to a processor of a general purpose computer, special purpose computer, or other programmable data processing apparatus to produce a machine, such that the instructions which execute via the processor of the computer, other programmable data processing apparatus, or other devices enable implementation of the functions/acts specified in the flowchart and/or block diagram block or blocks.

These computer program instructions may also be stored in a non-transitory computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The following documents are incorporated herein in their entirety by this reference for all purposes: European Patent Application 2402205A1, United States Patent Application 2012/0005031, U.S. Pat. No. 8,473,131, U.S. Patent Application Ser. No. 61/977,493 filed Apr. 9, 2014, U.S. patent application Ser. No. 14/681,415 filed Apr. 8, 2015, U.S. patent application Ser. No. 15/427,805 filed Feb. 8, 2017, and U.S. patent application Ser. No. 15/432,664 filed Feb. 14, 2017.

The following description is primarily directed towards a transport system for transporting an energy storage system wherein the energy storage system stores energy that can be converted into electrical energy and/or energy that is stored in the form of electrical energy. In other words, the energy storage system provides an output of electrical power from an internal stored energy source. The stored energy system is configured to receive an input of electrical power to recharge/replenish the internal stored energy source.

The energy storage system provides electrical power at or in the vicinity of one or more of the locations to which it is transported. The transport system is used to accomplish transport of the energy storage system from one location to one or more other locations and to provide electrical power to the energy storage system to recharge the internal stored energy source during at least a portion of the transit. In other words, the transport system moves the energy storage system and recharges the energy storage system during at least part of the move. The energy storage system can be mounted onto and demounted from the transport system.

According to one or more embodiments of the present invention, the energy storage system is a workpiece that is worked on by the transport system. The energy storage system may be substantially any type of energy storage system that is capable of receiving electrical power for replenishing its internal stored energy source and which can also be placed on, transported, then removed from the transport system.

According to one or more embodiments of the present invention, the energy storage system may be an energy storage system such as, but not limited to an energy storage system that comprises a battery, a capacitor, a hybrid capacitor, a fuel-cell, and combinations thereof. One or more examples of a suitable energy storage system are shown in the following commonly owned patents and patent applications the contents of which are incorporated herein in their entirety for all purposes by this reference: U.S. Pat. No. 9,542,742, U.S. Patent Application Ser. No. 61/977,493 filed Apr. 9, 2014, U.S. patent application Ser. No. 15/427,805 filed Feb. 8, 2017, and U.S. patent application Ser. No. 15/432,664 filed Feb. 14, 2017.

The energy storage system is a mobile energy storage system wherein it is not fixed to a single location. In other words, the energy storage system can be moved. Optionally, the energy storage system may comprise an electric power supply and a power coupling element. The power coupling element is connected with the electric power supply so as to enable a transfer of electric energy derived from the electric power supply to a load which consumes and/or uses the electric power.

Optionally, the energy storage system may comprise a cart and optionally the cart may be a motorized cart. The electric power supply is mounted on the cart or the motorized cart so as to enable locomotion of the electric power supply and power coupling element such as for moving from a first location to a second location. According to one or more embodiments of the present invention, the energy storage system further includes a control and communication system also supported on and connected with the motorized cart so that the energy storage system can move from a first location to a second location by remote control and/or commands from the control and communication system. As an option, the energy storage system includes one or more sensors connected with and/or integrated into the control and communication system. In other words, the energy storage system is mobile so that it can be moved and optionally may be motorized; optionally, it may also be self driven and/or driven via remote control. According to one or more embodiments of the present invention, the self driven energy storage system is configured for self propulsion only short distances such as less than 10 kilometers and at low speeds such as less than 20 kilometer/hour.

Alternatively, the energy storage system may be mounted without wheels such as on a pallet, a skid, other type of base, or combinations thereof; for this configuration, the energy storage system may be loaded onto or unloaded from the transport system using equipment such as, but not limited to, a forklift, a winch, a crane, and combinations thereof.

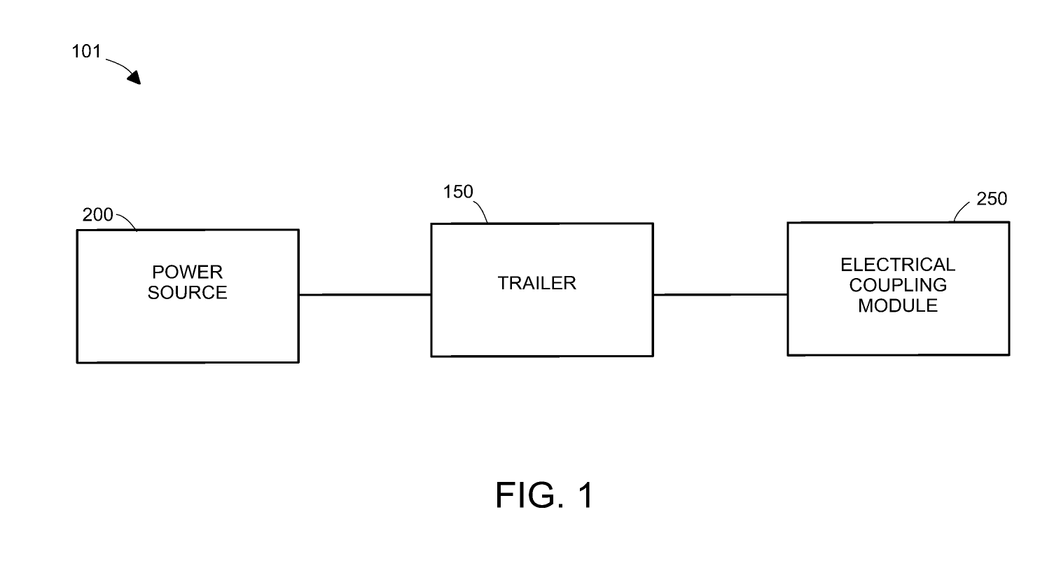

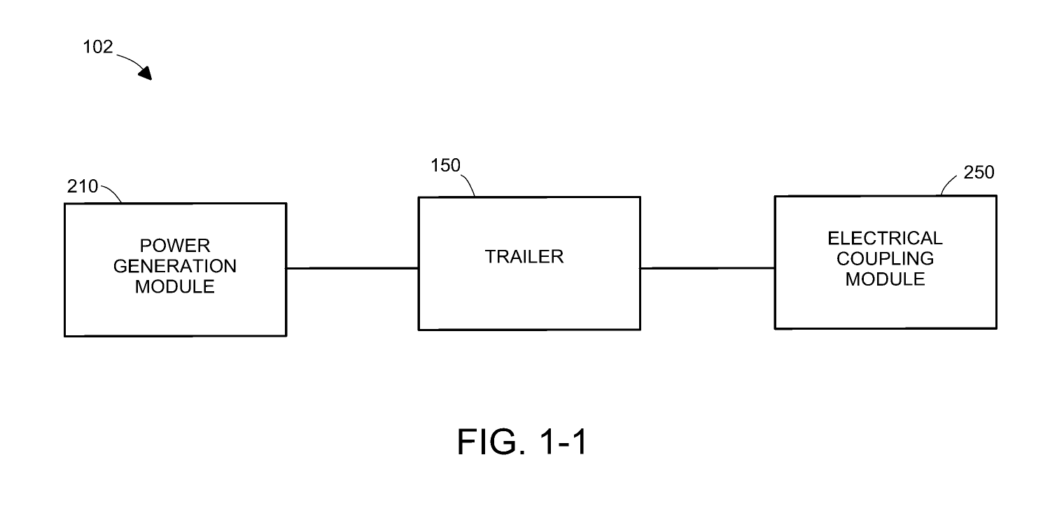

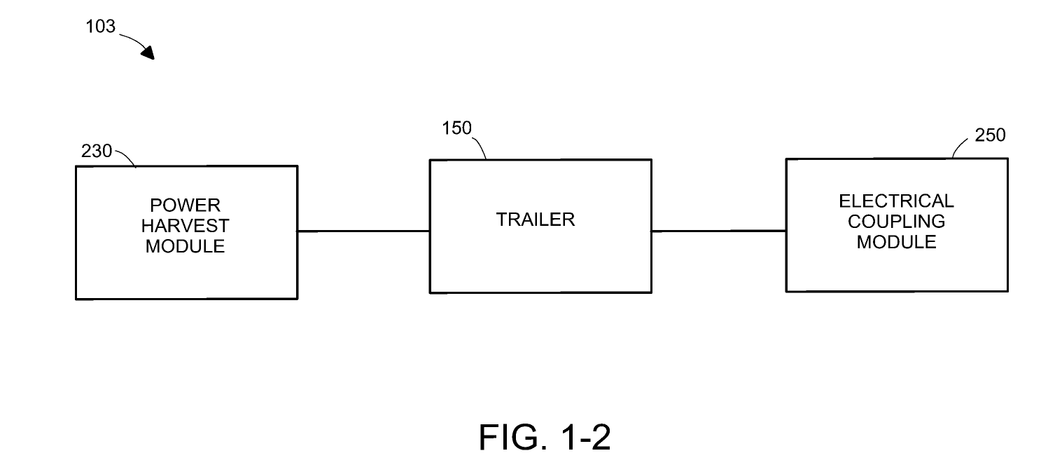

Reference is now made to FIG. 1 where there is shown a box diagram of a transport system 101 according to one or more embodiments of the present invention. Transport system 101 comprises a trailer 150, a power source 200 carried by trailer 150, and an electrical coupling module 250.

Trailer 150, for one or more embodiments of the present invention, may be substantially any vehicle having a body, a frame, a housing, and/or a platform to support an item for transport wherein the transport is accomplished by towing the trailer with an automotive vehicle. According to one or more embodiments of the present invention, trailer 150 is configured to transport an energy storage system substantially as described above and/or in commonly owned U.S. Pat. No. 9,592,742. According to one or more embodiments of the present invention, trailer 150 has at least one wheel rotatably coupled to a frame, a housing, and/or the platform and is configured to be towed by an automotive vehicle such as, but not limited to, an automobile, a car, a tractor (as in tractor trailer), a truck, and a van. Furthermore, trailer 150 may be configured for being towed over roads for durations of time to move the electric energy storage system from one location to another location.

According to one or more embodiments of the present invention, trailer 150 comprises a body, a frame, a housing, and/or a platform and one or more wheels rotatably coupled thereto for moving trailer 150. Trailer 150 has an area for receiving one or more energy storage systems. Trailer 150 further comprises one or more quick couple/quick release mechanical connectors connected with the body, the frame, the housing, and/or the platform so as to hold the self-propelled and/or self driven energy storage system. The quick couple/quick release mechanical connectors are used in place of substantially permanent connectors so as to allow faster loading, transport, and/or unloading of the energy storage systems being transported.

According to one or more embodiments of the present invention, the area for receiving the one or more energy storage systems may be configured to receive self-propelled and/or self driven energy storage systems. More specifically, trailer 150 may be configured so that the self-propelled and/or self driven energy storage systems may be self propelled and/or self driven onto trailer 150.

As another option, the area for receiving the one or more energy storage systems may be configured to receive energy storage systems which are not self-propelled and/or are not self driven. More specifically, trailer 150 may be configured so that the energy storage systems may be placed on trailer 150 such as by using a crane, forklift, winch, and/or other lifting equipment. According to one or more embodiments of the present invention, trailer 150 may be configured to receive self-propelled and/or self driven energy storage systems and/or energy storage systems which are not self-propelled and/or are not self driven.

For one or more embodiments of the present invention, power source 200 is fixedly coupled to trailer 150. Power source 200 may be implemented in one or more embodiments of the present invention in a variety of configurations. According to one embodiment of the present invention, power source 200 comprises a power generation module that collects, converts, and/or generates power from a primary energy source so as to be able to accomplish providing the collected, converted, and/or generated power from the primary source to the energy storage system so as to recharge the internal stored energy source of the energy storage system. According to another embodiment of the present invention, power source 200 comprises a power harvest module which recovers and/or reclaims energy expended to achieve transport of the energy storage system. According to another embodiment of the present invention, power source 200 comprises a power generation module, a power harvest module, or combinations thereof which may be operated at the same time or operated separately.

According one embodiment of the present invention, power source 200 comprises an electric energy source such as a fuel-cell. As an option for one or more embodiments using fuel cells, power source 200 may include a container for fuel so as to store a fuel supply onboard.

Another embodiment of the present invention has power source 200 comprising a chemical fuel driven electricity generator other than a fuel cell. In one configuration, the power source 200 comprises a chemical fuel driven electricity generator such as an internal combustion engine powered electricity generator. For chemical fuel driven electricity generators, power source 200 may comprise a container for fuel so as to store a fuel supply onboard. Optionally, the fuel used for generating the electricity may be derived from a renewable or carbon neutral source. Alternatively, one or more embodiments of the present invention may have power source 200 comprising a wind driven electricity generator. Alternatively, one or more embodiments of the present invention may have power source 200 comprising a solar energy driven electricity generator such as a solar thermal energy generator and/or a photovoltaic electricity generator. Alternatively, one or more embodiments of the present invention may have power source 200 comprising a thermoelectric or piezoelectric electricity generator.

According to one or more embodiments of the present invention power source 200 may comprise a power harvest module which recovers and/or reclaims energy expended to achieve transport of the energy storage system. In other words, the power harvest module recovers energy that would otherwise be wasted energy. The power harvest module may include mechanisms and apparatus to recover energy from braking such as regenerative braking, deceleration of trailer 150, and/or downhill movement of trailer 150. In other words, power source 200 may derive energy from a secondary energy source such as changes in momentum, changes in elevation, energy from deceleration, energy from down-hill driving (potential energy change), energy thermoelectrically from waste heat, energy piezoelectrically from excess motion, and/or energy from regenerative braking of the trailer that may be incidental during the towing of trailer 150.

According to one or more embodiments of the present invention, power source 200 may comprise a generator such as, but not limited to, an alternator and a dynamo that converts mechanical energy to electrical energy wherein the mechanical energy is derived from motion of the trailer. According to one or more embodiments, the generator may be mechanically driven by a rotatable coupling to one or more of the wheels of the trailer, one or more axles of the trailer, and/or the road surface. According to one or more embodiments, the generator may be mechanically driven by a flywheel and/or a gyroscope which may be rotationally coupled to one or more of the wheels of the trailer, one or more axles of the trailer, and/or the road surface.

According to one or more embodiments of the present invention, power source 200 may comprise a power generation module to produce hydrogen. More specifically, power source 200 may be configured such as to include a water electrolyzer to generate hydrogen from water wherein the hydrogen is used to power a fuel cell to produce electricity for charging the energy storage system.

According to one or more embodiments of the present invention, power source 200 may comprise a power generation module to convert mechanical energy into chemical fuel. Optionally, the chemical fuel may be stored for later use in which it is converted into electrical energy or other form of energy.

According to one or more embodiments of the present invention, power source 200 may comprise a power generation module to convert mechanical energy into compressed gas energy such as compressed air. Optionally, the compressed gas energy may be stored for later use in which it is converted into electrical energy or other form of energy.

According to one or more embodiments of the present invention, power source 200 may comprise a power generation module that generates electrical power from compressed air.

According to one or more embodiments of the present invention, power source 200 may comprise a power generation module that generates electrical power from compressed natural gas.

According to one or more embodiments of the present invention, power source 200 may comprise a power harvest module to convert mechanical energy into chemical fuel. Optionally, the chemical fuel may be stored for later use in which it is converted into electrical energy or other form of energy.

According to one or more embodiments of the present invention, power source 200 may comprise a power harvest module to convert mechanical energy into compressed gas energy.

According to one or more embodiments of the present invention, power source 200 may comprise a power harvest module to produce hydrogen.

According to one or more embodiments of the present invention, power source 200 may comprise a power harvest module comprising a hydrogen fuel cell and/or a water electrolyzer.

Transport system 101 includes electrical coupling module 250 to provide an electrical connection between power source 200 and the energy storage system so that the energy storage system can receive electrical power from power source 200 during at least a portion of the time of transporting the energy storage system. According to one or more embodiments of the present invention, electrical coupling module 250 comprises one or more quick couple/quick release electrical connectors to releasably connect power source 200 with the energy storage system during transport of the energy storage system. The quick couple/quick release electrical connectors are used in place of substantially permanent connectors so as to allow faster loading, transport, and/or unloading of the energy storage systems being transported.

Embodiments of the present invention may use a variety of types of electrical coupling module 250. Electrical power coupling module 250 may include electric connectors such as for providing low-power transmissions, medium power transmissions, and/or high-power transmissions by forming conductive and/or inductive power connections. As an example, electrical coupling module 250 may include a standard wall socket connector suitable for low-power transmission by conduction. Examples of wall socket connectors include, but are not limited to, Type A through Type O connectors. As another example, electrical coupling module 250 may include a standard wall socket connector for higher power transmission by conduction. As another example, electrical coupling module 250 may include a high-power transmission connector such as those used for high rate charging high-capacity batteries such as for electric vehicle chargers. Examples of some types of currently available conductive connectors designed for high rate power transmission such as for charging electric vehicles include but is not limited to, J1772 AC connector, CHAdeMO connector, and SAE Combo connector. Optionally, electric coupling module 250 may have more than one type of electrical connector. According one embodiment of the present invention, electrical coupling module 250 comprises a conductive connector and/or and inductive connector (such as an antenna) to couple electric power to the energy storage system.

According to one or more embodiments of the present invention, electrical coupling module 250 comprises a coil to inductively provide electric power to charge a battery or capacitor of the energy storage system. More specifically, inductively provided electric power is enabled by wireless charging which works with a transmitting-receiving coil system that couple to send energy via magnetic induction over a distance via over-the-air transmission. More specifically, there is no physical connection between the transmitting and receiving coil. Electrical coupling module 250 may include the transmitting coil. Electrical coupling module 250 uses the transmitting coil to provide electricity at a suitable frequency for over-the-air wireless electricity transfer to the energy storage system which includes a receiving coil using magnetic induction or magnetic resonance.

Reference is now made to FIG. 1-1 where there is shown a diagram of a transport system 102 according to one or more embodiments of the present invention. Transport system 102 comprises a trailer 150, a power generation module 210, and an electrical coupling module 250.

Trailer 150 may be substantially any vehicle having a frame, a housing, and/or a platform to support an item for transport wherein the transport is accomplished by towing the trailer with an automotive vehicle. According to one or more embodiments of the present invention, trailer 150 shown in FIG. 1-1 is essentially the same as trailer 150 described above for the embodiment shown in and described for FIG. 1. Electrical coupling module 250 shown in FIG. 1-1 is essentially the same as electrical coupling module 250 described above for the embodiment shown in and described for FIG. 1.

FIG. 1-1 shows transport system 102 having power generation module 210 carried by trailer 150. As an option, power generation module 210 may be fixedly attached to trailer 150. According to one embodiment of the present invention, power generation module 210 comprises mechanisms and apparatuses to collect, convert, and/or generate power from a primary energy source so as to be able to accomplish providing the collected, converted, and/or generated power from the primary energy source to the energy storage system so as to recharge the internal stored energy source of the energy storage system.

According one embodiment of the present invention, power generation module 210 comprises an electric energy source such as a fuel-cell. As an option for one or more embodiments using fuel cells, power generation module 210 may include a container for fuel so as to store a fuel supply onboard.

Another embodiment of the present invention has power generation module 210 comprising a chemical fuel driven electricity generator other than a fuel cell. In one configuration, power generation module 210 comprises a chemical fuel driven electricity generator such as an internal combustion engine driven electricity generator. For chemical fuel driven electricity generators, generation module 210 may comprise a container for fuel so as to store a fuel supply onboard. Optionally, the fuel used for generating the electricity may be derived from a renewable or carbon neutral source.

Alternatively, one or more embodiments of the present invention may have power generation module 210 comprising a wind driven electricity generator such as but not limited to, a windmill, a wind turbine, and combinations thereof. Alternatively, one or more embodiments of the present invention may have power generation module 210 comprising a solar energy driven electricity generator such as a solar thermal energy driven generator and/or a photovoltaic electricity generator. Alternatively, one or more embodiments of the present invention may have power generation module 210 comprising a thermoelectric or piezoelectric electricity generator.

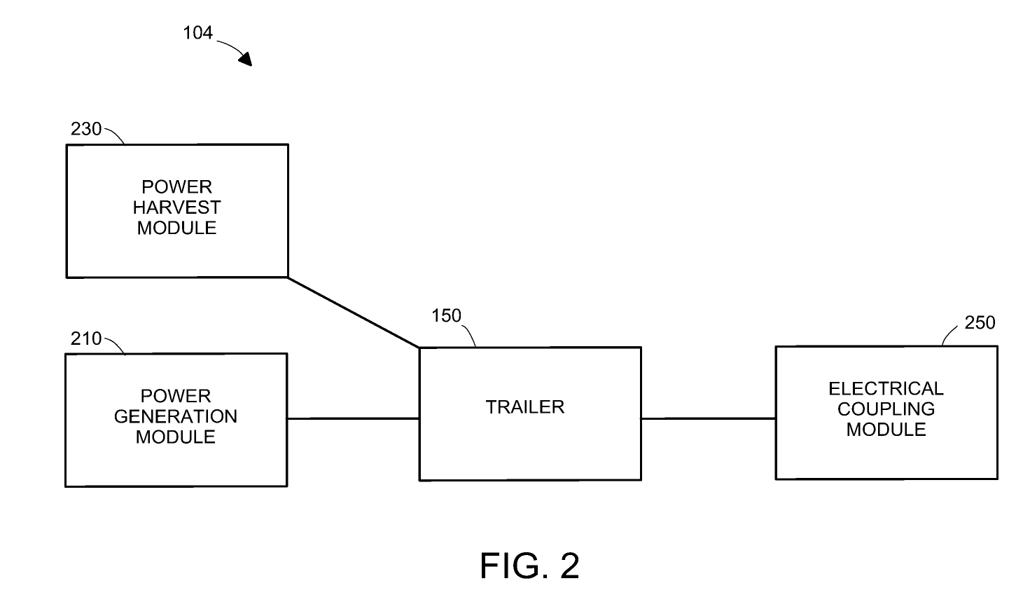

Reference is now made to FIG. 1-2 where there is shown a block diagram of a transport system 103 according to one or more embodiments of the present invention. Transport system 103 comprises a trailer 150, a power harvest module 230, and an electrical coupling module 250.

According to one or more embodiments of the present invention, trailer 150 shown in FIG. 1-2 is essentially the same as trailer 150 described above for the embodiment shown in and described for FIG. 1. Electrical coupling module 250 shown in FIG. 1-2 is essentially the same as electrical coupling module 250 described above for the embodiment shown in and described for FIG. 1.

FIG. 1-2 shows transport system 103 having power harvesting module 230 carried by trailer 150. As an option, power harvest module 230 may be fixedly attached to trailer 150. According to one embodiment of the present invention, power harvest module 230 comprises mechanisms and apparatuses to recover and/or reclaim energy expended to achieve transport of the energy storage system.

According to one or more embodiments of the present invention, power harvest module 230 recovers and/or reclaims energy expended to achieve transport of the energy storage system. In other words, power harvest module 230 recovers energy that might otherwise be wasted energy. The power harvest module may include mechanisms and apparatuses to recover energy from braking and/or deceleration of trailer 150 and/or downhill movement of trailer 150. In other words, for one or more embodiments of the present invention, power harvest module 230 may derive energy from a secondary energy source such as changes in momentum and/or changes in elevation that may occur during the towing of trailer 150.

Reference is now made to FIG. 2 where there is shown a block diagram of a transport system 104 according to one or more embodiments of the present invention. Transport system 104 comprises a trailer 150, a power generation module 210, a power harvest module 230, and an electrical coupling module 250.

According to one or more embodiments of the present invention, trailer 150 shown in FIG. 2 is essentially the same as trailer 150 described above for the embodiment shown in and described for FIG. 1. Electrical coupling module 250 shown in FIG. 2 is essentially the same as electrical coupling module 250 described above for the embodiment shown in and described for FIG. 1.

FIG. 2 shows transport system 104 having power generation module 210 carried by trailer 150. As an option, power generation module 210 may be fixedly attached to trailer 150. According to one embodiment of the present invention, power generation module 210 comprises mechanisms and apparatuses to collect, convert, and/or generate power from a primary energy source so as to be able to accomplish providing the collected, converted, and/or generated power from the primary energy source to the energy storage system so as to recharge the internal stored energy source of the energy storage system.

According one embodiment of the present invention, power generation module 210 comprises an electric energy source such as a fuel-cell. As an option for one or more embodiments using fuel cells, power generation module 210 may include a container for fuel so as to store a fuel supply onboard.

Another embodiment of the present invention has power generation module 210 comprising a chemical fuel driven electricity generator other than a fuel cell. In one configuration, power generation module 210 comprises a chemical fuel driven electricity generator such as an internal combustion engine powered electricity generator. For chemical fuel powered electricity generators, generation module 210 may comprise a container for fuel so as to store a fuel supply onboard. Optionally, the fuel used for generating the electricity may be derived from a renewable or carbon neutral source. Alternatively, one or more embodiments of the present invention may have power generation module 210 comprising a wind driven electricity generator such as but not limited to, a windmill, a wind turbine, and combinations thereof. Alternatively, one or more embodiments of the present invention may have power generation module 210 comprising a solar energy driven electricity generator such as a solar thermal energy generator and/or a photovoltaic electricity generator. Alternatively, one or more embodiments of the present invention may have power generation module 210 comprising a thermoelectric or piezoelectric electricity generator.

FIG. 2 shows transport system 104 having power harvesting module 230 carried by trailer 150. As an option, power harvest module 230 may be fixedly attached to trailer 150. According to one embodiment of the present invention, power harvest module 230 comprises mechanisms and apparatuses to recover and/or reclaim energy expended to achieve transport of the energy storage system.

According to one or more embodiments of the present invention, power harvest module 230 recovers and/or reclaims energy expended to achieve transport of the energy storage system. In other words, power harvest module 230 recovers energy that might otherwise be wasted energy. The power harvest module may include mechanisms an apparatus to recover energy from braking and/or deceleration of trailer 150 and/or downhill movement of trailer 150. In other words, for one or more embodiments of the present invention, power harvest module 230 may derive energy from a secondary energy source such as changes in momentum and/or changes in elevation that may occur during the towing of trailer 150.

It is to be understood that embodiments of the present invention may include power generation module 210 and/or power harvest module 230. It is also to be understood that power generation module 210 may be used independently, power harvest module 230 may be used independently, or power generation module 210 and power harvest 230 may be used in combination to provide electric power to the energy storage system.

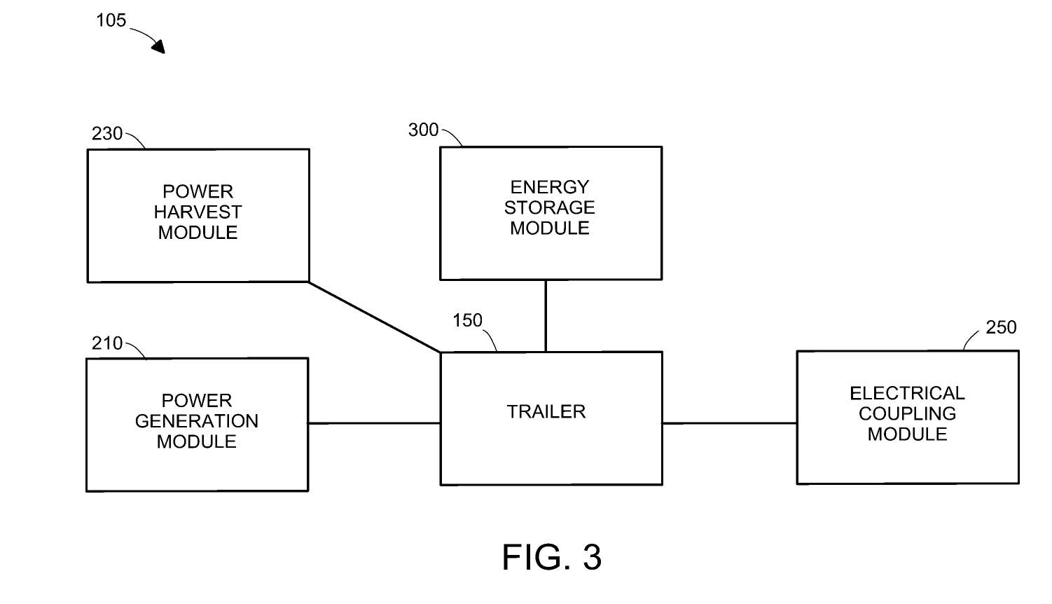

Reference is now made to FIG. 3 where there is shown a block diagram of a transport system 105 according to one or more embodiments of the present invention. Transport system 105 comprises a trailer 150, a power generation module 210, a power harvest module 230, an electrical coupling module 250, and an energy storage module 300.

According to one or more embodiments of the present invention, trailer 150 shown in FIG. 3 is essentially the same as trailer 150 described above for the embodiment shown in and described for FIG. 1. Power generation module 210 is essentially the same as power generation module 210 shown in and described above for FIG. 2. Power harvest module 230 is essentially the same as power harvest module 230 shown in and described above for FIG. 2. Electrical coupling module 250 shown in FIG. 3 is essentially the same as electrical coupling module 250 described above for the embodiment shown in and described above for FIG. 1.

Energy storage module 300 is carried by trailer 150. According to one or more embodiments of the present invention energy storage module 300 is fixedly attached to trailer 150. Also according to one or more embodiments of the present invention, energy storage module 300 may be electrically connected with electrical coupling module 254 transfer of power from energy storage module 300 to the energy storage system being transported. In other words, energy storage module 300 stores energy in a form that can be converted into electrical energy or stores electrical energy that can be used to recharge the internal stored energy source of the energy storage system. More specifically, transport system 105 provides the option of delivering electrical power to the energy storage system wherein the electric power is derived from power generation module 210, power harvest module 230, and/or energy storage module 300.

Optionally energy storage module 300 provides a reservoir for energy storage such as for situations in which power generation module 210 and/or power harvest module 230 are acquiring energy which cannot be provided as input to the energy storage system. In other words, energy storage module 300 is available for storing energy in situations such as when an energy storage system is not being transported by the trailer and such as when an energy storage system being transported has been fully charged.

According to one or more embodiments of the present invention, energy storage module 300 may comprise a variety of energy storage mechanisms. Examples of types of energy storage mechanisms that can be utilized in energy storage module 300 include, but are not limited to batteries, capacitors, hybrid batteries, and combinations thereof.

Optionally, energy storage module 300 may comprise a chemical fuel storage container. For example, a chemical fuel storage container may be configured for storing hydrogen which may be produced by electrolysis of water using power from power generation module 210 and/or power harvest module 230.

Optionally, energy storage module 300 may comprise a compressed gas storage container for storing gas at high pressure which can then be used to drive a turbine to generate electricity such as is used in compressed air technology energy storage and conversion systems.

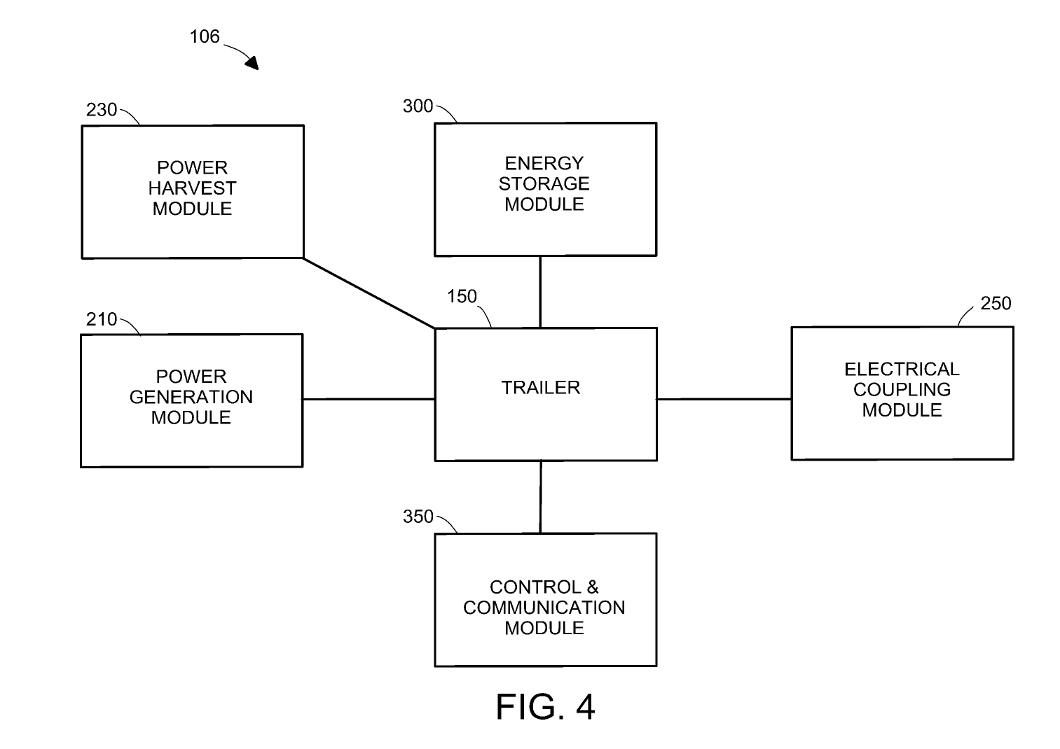

Reference is now made to FIG. 4 where there is shown a block diagram of a transport system 106 according to one or more embodiments of the present invention. Transport system 105 comprises a trailer 150, a power generation module 210, a power harvest module 230, an electrical coupling module 250, an energy storage module 300, and a control and communication module 350.

According to one or more embodiments of the present invention, trailer 150 shown in FIG. 4 is essentially the same as trailer 150 described above for the embodiment shown in and described for FIG. 1. Power generation module 210 shown in FIG. 4 is essentially the same as power generation module 210 shown in and described above for FIG. 2. Power harvest module 230 shown in FIG. 4 is essentially the same as power harvest module 230 shown in and described above for FIG. 2. Electrical coupling module 250 shown in FIG. 4 is essentially the same as electrical coupling module 250 described above for the embodiment shown in and described above for FIG. 1. Energy storage module 300 shown in FIG. 4 is essentially the same as energy storage module 300 shown in FIG. 3.

Control and communication module 350 is carried by trailer 150. Control and communication module 350 may have a variety of configurations for one or more embodiments of the present invention. According to one embodiment of the present invention, control and communication module 350 comprises a computer, a central processing unit, a microprocessor, an electronic memory, an application specific integrated circuit, a field programmable gate array, an information processor, or combinations thereof. Embodiments of the present invention may also have control and communication module 350 further comprising a transmitter circuit, a receiver circuit, a display, a user interface, or combinations thereof. According to one or more embodiments of the present invention, control and communication module 350 comprises a global positioning system to provide location information for transport system 106. The location information can be used for calculations such as making predictions of amounts of potential charging of an energy storage system for transport of the energy storage system from its present location to another location.

According to one or more embodiments of the present invention, control and communication module 350 comprises a computer program product for monitoring and controlling charging of the energy storage system. The computer program product is embodied in a non-transitory computer readable medium and comprises computer instructions for controlling the power transfer from a power source such as power source 200, power generation module 210, power harvest module 230, and/or energy storage module 300. Optionally, the non-transitory computer readable medium may reside entirely on control and communication module 350 or at a remote location such as a network location, a cloud storage location, a network server, or combinations thereof.

According to one or more embodiments of the present invention, control and communication module 350 may be connected to a power source such as power source 200, power generation module 210, power harvest module 230, energy storage module 300, and/or the energy storage system so as to accomplish information transfer, instruction transfer, and other types of communication.

According to one or more embodiments of the present invention, control and communication module 350 may include a transmitter circuit and/or receiver circuit embodied in a transmitter or receiver such as those typically used for electronic device communication systems. Examples of electronic device transmitter systems suitable for one or more embodiments of the present invention include, but are not limited to, cellular communication, radio communication, satellite communication, and combinations thereof.

According to one or more embodiments of the present invention, control and communication module 350 may further comprise one or more sensors (sensors not shown in FIG. 4) for collecting data and providing information for processing by control and communication module 350. The sensors may perform a variety of functions to provide information for operation of transport system 106. According to one embodiment of the present invention, one or more sensors are responsive to the operational state of power generation module 210, power harvest module 230, energy coupling module 250, and/or energy storage module 300 and are disposed so as to provide data to control and communication module 350. According to another embodiment of the present invention, one or more sensors are included which provide data about the surroundings of transport system 106 such as weather conditions such as relative humidity, rain, temperature, and fog, and combinations thereof.

According to one or more embodiments of the present invention, control and communication module 350 comprises hardware and/or software to accomplish operation of transport system 106. According to one or more embodiments of the present invention, communication and control system 350 comprises hardware and/or software to accomplish machine-learning operations so as to continue to improve the performance of transport system 106 based on the data collected from the sensors. Performance parameters that may be improved include, but are not limited to, effectiveness and/or efficiency of providing electric power to the energy storage system, optimization of use of the transport system, and/or optimization of use of the energy storage system.

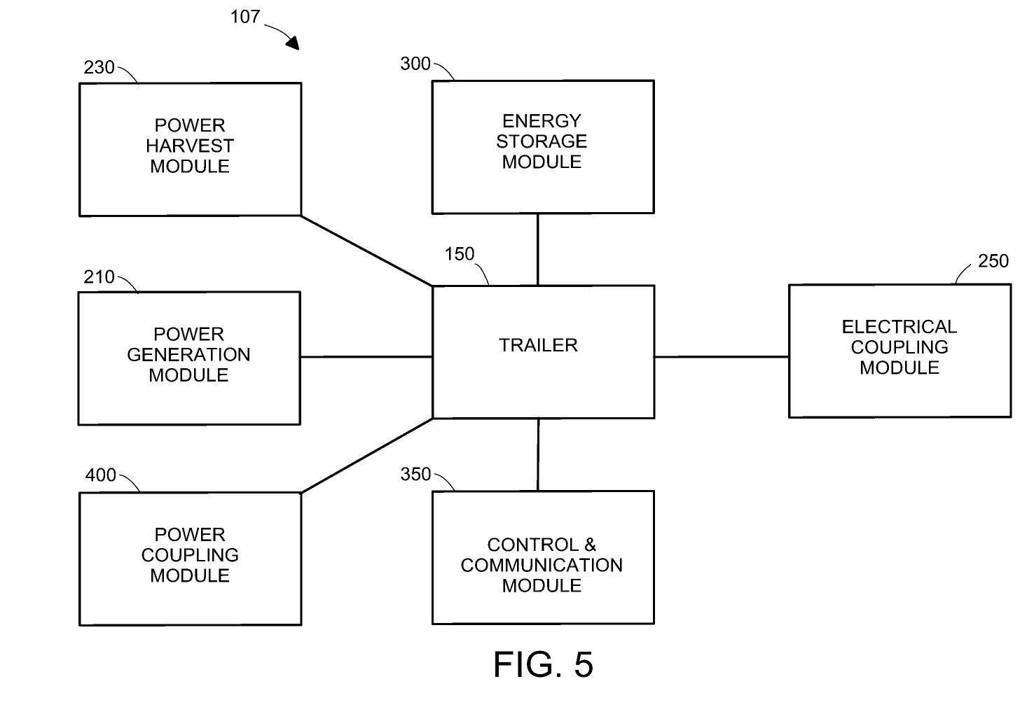

Reference is now made to FIG. 5 where there is shown a block diagram of a transport system 107 according to one or more embodiments of the present invention. Transport system 107 comprises a trailer 150, a power generation module 210, a power harvest module 230, an electrical coupling module 250, an energy storage module 300, a control and communication module 350, and a power coupling module 400.

According to one or more embodiments of the present invention, trailer 150 shown in FIG. 5 is essentially the same as trailer 150 described above for the embodiment shown in and described for FIG. 1. Power generation module 210 shown in FIG. 5 is essentially the same as power generation module 210 shown in and described above for FIG. 2. Power harvest module 230 shown in FIG. 5 is essentially the same as power harvest module 230 shown in and described above for FIG. 2. Electrical coupling module 250 shown in FIG. 5 is essentially the same as electrical coupling module 250 described above for the embodiment shown in and described above for FIG. 1. Energy storage module 300 shown in FIG. 5 is essentially the same as energy storage module 300 shown in FIG. 3. Control and communication module 350 shown in FIG. 5 is essentially the same as Control and communication module 350 shown in FIG. 4.

Power coupling module 400 comprises one or more electrical connections to provide electrical power to a load which consumes and/or uses the electric power. Power coupling module 400 is connected with power generation module 210, power harvest module 230, and/or energy storage module 300 to receive electric power for delivery to the load. Power coupling module 400 may include a variety of types of electrical connections to accommodate various types of loads. Power coupling module 400 may include electric connectors such as for providing low-power transmissions, medium power transmission, and/or high-power transmissions by forming conductive and/or inductive power connections. According to one or more embodiments of the present invention, power coupling module 400 is configured to provide power to loads such as, but not limited to, power tools, light sources, battery packs such as those used for power tools, batteries, capacitors, and electric vehicles.

As an example, power coupling module 400 may include a standard wall socket connector suitable for low-power transmission by conduction. Examples of wall socket connectors include, but are not limited to, National Electrical manufacturers Association (NEMA) connectors and Type A through Type O connectors. As another example, power coupling module 400 may include a standard wall socket connector for higher power transmission by conduction. As another example, power coupling module 400 may include a high-power transmission connector such as those used for high rate charging high-capacity batteries such as for electric vehicle chargers. Examples of some types of currently available conductive connectors designed for charging electric vehicles include but is not limited to, J1772 AC connector, CHAdeMO connector, and SAE Combo connector. Optionally, power coupling module 400 may have more than one type of electrical connector.

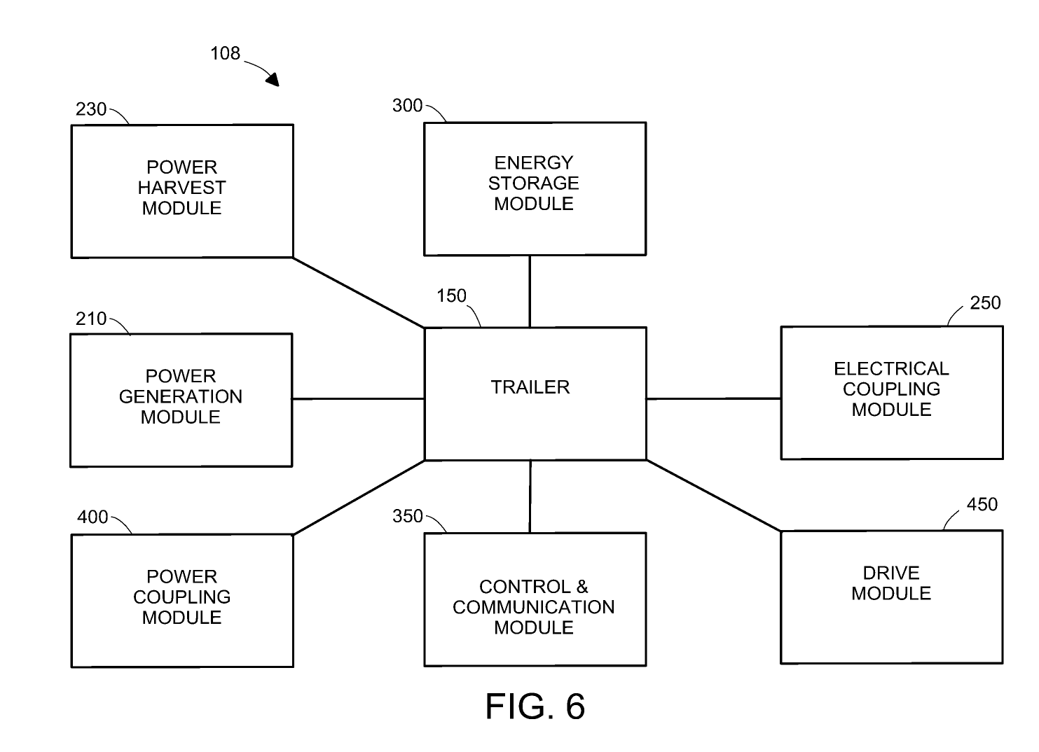

Reference is now made to FIG. 6 where there is shown a block diagram of a transport system 108 according to one or more embodiments of the present invention. Transport system 108 comprises a trailer 150, a power generation module 210, a power harvest module 230, an electrical coupling module 250, an energy storage module 300, a control and communication module 350, a power coupling module 400, and a drive module 450.

According to one or more embodiments of the present invention, trailer 150 shown in FIG. 6 is essentially the same as trailer 150 described above for the embodiment shown in and described for FIG. 1. Power generation module 210 shown in FIG. 6 is essentially the same as power generation module 210 shown in and described above for FIG. 2. Power harvest module 230 shown in FIG. 6 is essentially the same as power harvest module 230 shown in and described above for FIG. 2. Electrical coupling module 250 shown in FIG. 6 is essentially the same as electrical coupling module 250 described above for the embodiment shown in and described above for FIG. 1. Energy storage module 300 shown in FIG. 6 is essentially the same as energy storage module 300 shown in and described above for FIG. 3. Control and communication module 350 shown in FIG. 6 is essentially the same as control and communication module 350 shown in and described above for FIG. 4. Power coupling module 400 shown in FIG. 6 is essentially the same power coupling module 400 shown in and described above for FIG. 5.

Drive module 450 is carried by trailer 150. According to one or more embodiments of the present invention, drive module 450 comprises a motor, an engine, or other drive system rotatably coupled to one or more wheels of trailer 150 to accomplish locomotion of trailer 150, i.e. movement from place to place, such as from a first location to a second location without being towed. According to one or more embodiments of the present invention, drive module 450 may receive power from energy storage module 300, power generation module 210, another power source, or combinations thereof.

According to one or more embodiments of the present invention, drive module 450 may be connected with control and communication module 350 for information and instruction transfer. For example, control and communication module 350 may be connected with drive system 450 so as to monitor the operation of drive module 450. As another example, control and communication module 350 may be connected with drive system 450 so as to control the operation of drive module 450. According to one or more embodiments of the present invention, control and communication module 350 may be used to provide commands to drive system 450 so as to make transport system 108 capable of driving itself from one location to another location. According to one or more embodiments of the present invention, control and communication module 350 may be used to provide commands to drive system 450 so as to make transport system 108 capable of being driven by remote control from signals received by wired or wireless communication.

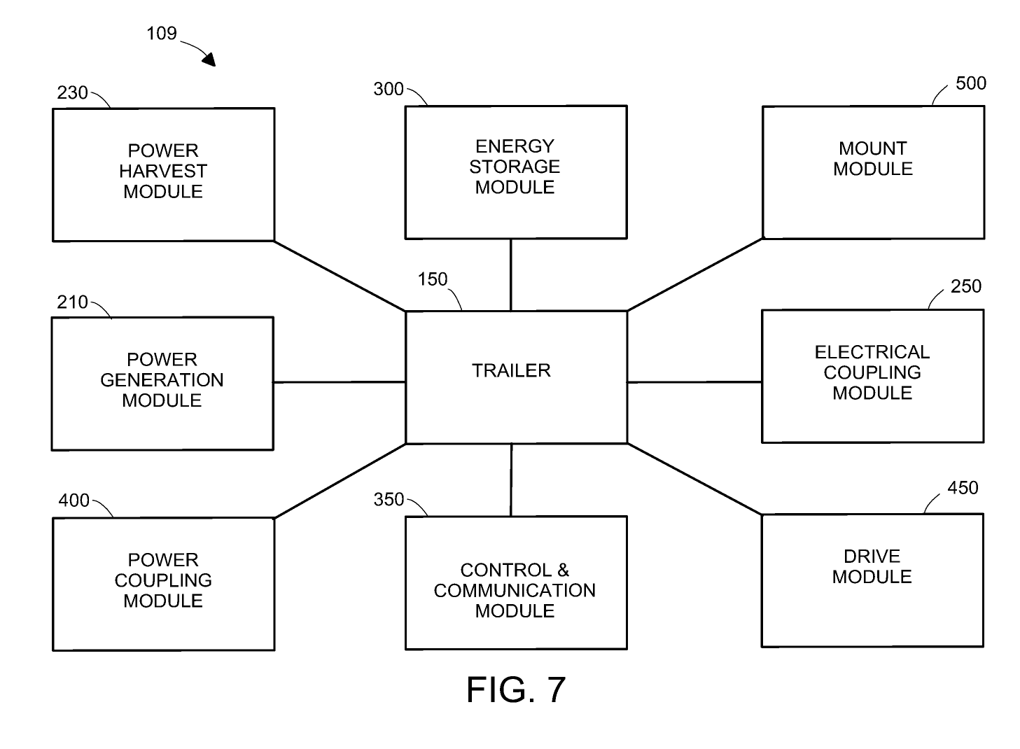

Reference is now made to FIG. 7 where there is shown a block diagram of a transport system 109 according to one or more embodiments of the present invention. Transport system 109 comprises a trailer 150, a power generation module 210, a power harvest module 230, an electrical coupling module 250, an energy storage module 300, a control and communication module 350, a power coupling module 400, a drive module 450, and a mount module 500.

According to one or more embodiments of the present invention, trailer 150 shown in FIG. 7 is essentially the same as trailer 150 described above for the embodiment shown in and described for FIG. 1. Power generation module 210 shown in FIG. 7 is essentially the same as power generation module 210 shown in and described above for FIG. 2. Power harvest module 230 shown in FIG. 7 is essentially the same as power harvest module 230 shown in and described above for FIG. 2. Electrical coupling module 250 shown in FIG. 7 is essentially the same as electrical coupling module 250 described above for the embodiment shown in and described above for FIG. 1. Energy storage module 300 shown in FIG. 7 is essentially the same as energy storage module 300 shown in and described above for FIG. 3. Control and communication module 350 shown in FIG. 7 is essentially the same as Control and communication module 350 shown in and described above for FIG. 4. Power coupling module 400 shown in FIG. 7 is essentially the same power coupling module 400 shown in and described above for FIG. 5. Drive module 450 shown in FIG. 7 is essentially the same drive module 450 shown in and described above for FIG. 6.

Mount module 500 comprises apparatuses that may be used for physically supporting and/or holding the energy storage system during transport. According to one or more embodiments of the present invention, mount module 500 may comprise structures such as, but not limited to, a frame, a pedestal, a track, and combinations thereof. Optionally mount module 500 may include one or more attachment mechanisms, connectors, and/or clamps to hold the energy storage system in place on trailer 150. According to one or more embodiments of the present invention, mount module 500 may include electrical connectors and/or may be integrated with electrical coupling module 250 to make electrical connections to the energy storage system. According to one or more embodiments of the present invention mount module 500 may include quick connect and quick disconnect attachment mechanisms for holding the energy storage system. According to one or more embodiments of the present invention, mount module 500 may include quick connect and quick disconnect electrical connection.

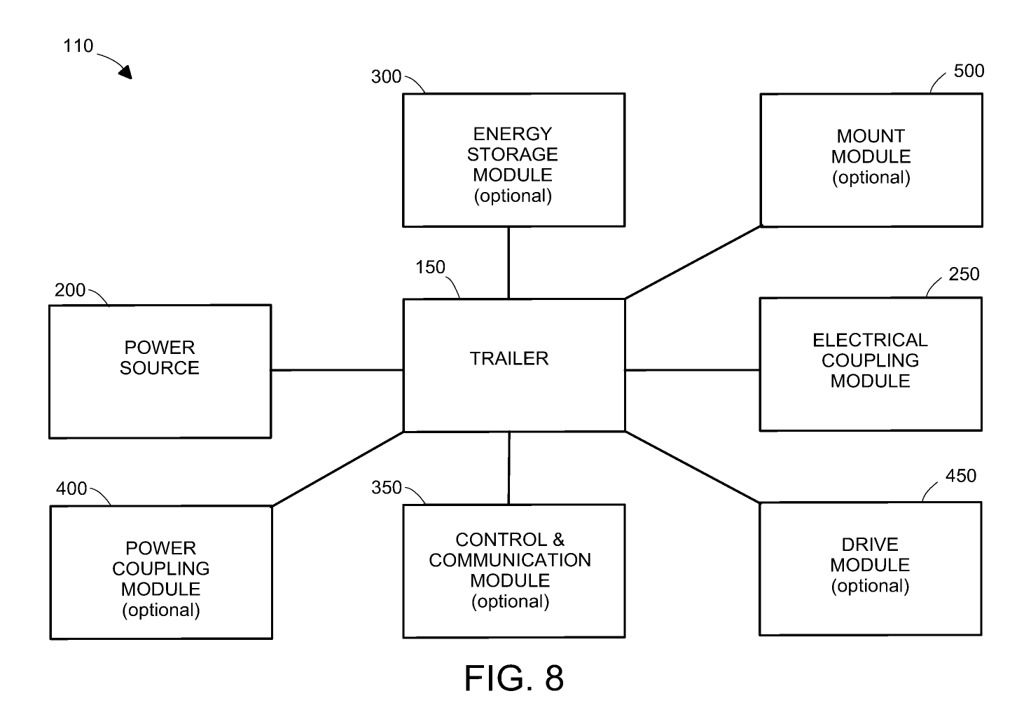

Reference is now made to FIG. 8 where there is shown a block diagram of a transport system 110 according to one or more embodiments of the present invention. Transport system 110 comprises a trailer 150, a power source 200, an electrical coupling module 250, an optional energy storage module 300, an optional control and communication module 350, and optional power coupling module 400, an optional drive module 450, and an optional mount module 500. In other words, various embodiments of the present invention may be derived from the presence or absence of the optional modules which may include any of or all possible combinations of the optional modules being present.

According to one or more embodiments of the present invention, trailer 150 shown in FIG. 8 is essentially the same as trailer 150 described above for the embodiment shown in and described for FIG. 1. Power source module 200 shown in FIG. 8 is essentially the same as power source 200 shown in and described above for FIG. 1. Power harvest module 230 shown in FIG. 8 is essentially the same as power harvest module 230 shown in and described above for FIG. 2. Electrical coupling module 250 shown in FIG. 8 is essentially the same as electrical coupling module 250 described above for the embodiment shown in and described above for FIG. 1. Energy storage module 300 shown in FIG. 8 is essentially the same as energy storage module 300 shown in and described above for FIG. 3. Control and communication module 350 shown in FIG. 8 is essentially the same as Control and communication module 350 shown in and described above for FIG. 4. Power coupling module 400 shown in FIG. 8 is essentially the same power coupling module 400 shown in and described above for FIG. 5. Drive module 450 shown in FIG. 8 is essentially the same drive module 450 shown in and described above for FIG. 6. Mount module 500 shown in FIG. 8 is essentially the same mount module 500 shown in and described above for FIG. 7.

According to one or more embodiments of the present invention, transport system 110 includes power coupling module 400 integrated with trailer 150, energy storage module 300 integrated with trailer 150. Power coupling module 400, energy storage module 300, and power source 200 are joined to provide electrical power to a load such as, but not limited to power tools, light sources, battery packs, batteries, capacitors, and combinations thereof.

According to one or more embodiments of the present invention, transport system 110 includes drive module 450 integrated with trailer 150 to provide locomotion of trailer 150. Drive module 450 comprises a motor and/or an engine. System 110 further comprising a remote control module (not shown in FIG. 8) configured to communicate with control and communication module 350 or another communication module. Drive module 450 is configured to be responsive to commands directly from the remote control module and/or indirectly via the control and communication module so as to accomplish remote control of the movement of transport system 110 using drive module 450.

According to one or more embodiments of the present invention, transport system 110 includes drive module 450 integrated with trailer 150 to provide locomotion of trailer 150. Drive module 450 comprises a motor and/or an engine. System 110 further comprising a remote control module (not shown in FIG. 8) comprising a wired or wireless joystick, a wired or wireless software enabled smart digital device, and/or a wired or wireless analog circuit device configured to communicate with control and communication module 350 or another communication module. Drive module 450 is configured to be responsive to commands directly from the remote control module and/or indirectly via the control and communication module so as to accomplish remote control of the movement of transport system 110 using drive module 450.

According to one or more embodiments of the present invention, transport system 110 includes drive module 450 integrated with trailer 150 to provide locomotion of trailer 150. Drive module 450 comprises a motor and/or an engine. Drive module 450 is configured to be responsive to commands from the control and communication module so as to accomplish autonomous control of the movement of transport system 110 using drive module 450 from one position to another position.

According to one or more embodiments of the present invention, transport system 110 further comprises one or more sensors on at least one wheel of trailer 150. The one or more sensors are coupled to transmit data to control and communication module 350 to automatically select a mode of operation for transport system 110.

According to one or more embodiments of the present invention, transport system 110 further comprises one or more sensors on at least one wheel of trailer 150 coupled to transmit data to control and communication module 350 to automatically select a mode of operation for transport system 110. Possible modes of operation may be selected that include, but are not limited to, providing maximum power to charge the energy storage system, providing less than maximum power to charge the energy storage system, and not charging the energy storage system.

According to one or more embodiments of the present invention, transport system 110 has trailer 115 including an area for receiving one or more self-propelled and/or self driven energy storage systems. The area for receiving one or more self-propelled and/or self driven energy storage systems comprises a track and a mechanical coupling mechanism for forming a releasable quick connect/quick disconnect connection with one or more self-propelled and/or self driven energy storage systems. The mechanical coupling mechanism, as an option, may be slidably attached to the track for movable placement of the one or more self-propelled and/or self driven energy storage systems on the track.

According to one or more embodiments of the present invention, transport system 110 has trailer 150 including an area for receiving one or more energy storage systems. The area for receiving one or more energy storage systems comprises a track. The track is connected with electrical coupling module 250 so that placement of the energy storage system on the track completes an electrical connection with electrical coupling module 250 to provide power to the energy storage system.

According to one or more embodiments of the present invention, transport system 110 further comprises a power shutoff switch integrated with power source 200 and/or electrical coupling module 250. The power shutoff switch is operable to terminate power transfer in response to a mechanically activated signal, a wirelessly activated signal, measurements from a sensor, or combinations thereof.

According to one or more embodiments of the present invention, transport system 110 further comprises a remote control module (not shown in FIG. 8) which comprises a computer, a mobile computer, a tablet computer, a joystick, a smart phone, device application controls, or other control mechanisms for controlling movement of the transport system 110. In other words, transport system 110 comprises hardware and/or software to accomplish remote control operation of transport system 110. Optionally, the remote control module and control and communication module 350 may be connected by hardware such as hardwiring or optical fiber for information exchange. Alternatively, the remote control module and control and communication module 350 may be wirelessly connected for information exchange. Optionally, remote-control may be performed by a user having direct sight of transport system 110 or by a user having a camera view of the location and transport system 110.

Another aspect of the present invention pertains to a method of transporting an energy storage system. According to one embodiment, the method is performed on an energy storage system. The method comprises providing a trailer, providing a power source coupled with the trailer, and providing a controller connected with the energy storage system and connected with the power source to accomplish information transfer and communication. Optionally, the power source is detachably coupled to the trailer or it may be fixedly coupled to the trailer. The method also includes providing one or more sensors coupled to the controller to provide data. The method includes releasably carrying the energy storage system on the trailer; in other words, the energy storage system is not permanently attached to the trailer. The method further includes allowing the controller to use information from the power source, information from the energy storage system, and from the one or more sensors to determine whether: to allow charging of the energy storage system by the power source and using the power source to charge the energy storage system while the energy storage system is being transported on the trailer or not to allow charging of the energy storage system by the power source while the energy storage system is being transported on the trailer.

According to one or more embodiments of the method, the providing a power source comprises providing a power generation module that converts mechanical energy to electrical energy wherein the mechanical energy is derived from motion of the trailer.

According to one or more embodiments of the method, the controller uses projected trip data and/or predefined criteria to determine charging rate and/or other charging parameters for charging the energy storage system.

According to one or more embodiments of the method, the energy storage system is self propelled. The method further comprises allowing the energy storage system to propel itself onto the trailer.

According to one or more embodiments of the method, the energy storage system is self propelled and self driven. The method further comprises allowing the energy storage system to drive itself onto the trailer.

According to one or more embodiments of the method, the energy storage system is self propelled and self driven. The method further comprises allowing the energy storage module to drive itself onto the trailer and to form an electrical connection with the power source to accomplish electrical energy transfer and to form a quick couple/quick release mechanical attachment to the trailer.

According to one or more embodiments of the method, the providing a power source comprises providing an energy harvesting module to recover energy from deceleration, down-hill driving (potential energy change), and/or regenerative braking of the trailer.

According to one or more embodiments of the method, the providing a power source comprises providing an energy harvesting module to recover energy thermoelectrically from waste heat and/or piezo-electrically from excess motion.

According to one or more embodiments of the method, the providing a power source comprises: providing a generator that converts mechanical energy to electrical energy wherein the mechanical energy is derived from movement of the trailer; providing an energy harvesting module to recover energy from deceleration, down-hill driving (potential energy change), and/or regenerative braking of the trailer; and/or providing an energy harvesting module to recover energy thermoelectrically from waste heat and/or piezo-electrically from waste motion.

According to one or more embodiments, the method further comprises providing an energy storage module integrated with the trailer and the power source to receive excess power from the power source to store energy. The method also comprises coupling energy from the energy storage module to the energy storage system so as to charge the energy storage system.

Another aspect of the present invention pertains to a data network such as a computer network. The data network may be a remote network such as a cloud-based network or internet. The data network may be implemented as a combination of data processors, computers, servers, communication devices, routers, gateways, software, multiple networks, or combinations thereof. Transport systems according to one or more embodiments presented above and the data network may be configured to have communication links for information transfer which may be accomplished, at least in part, using control and communication modules of the of the transport systems. According to one or more embodiments, the transport systems also include one or more information communication devices which have communication links with the data network.

According to one or more embodiments of the present invention, information collected and stored by the data network is used for data analytics for performance monitoring, performance optimization, and improving performance efficiency for transporting and charging the energy storage systems. Information may also be used to make performance predictions such as the amount of charging that can be achieved during transport of an energy storage system and may include factors such as the mode of operation, route, and other factors. Information may also be used to make performance predictions such as maintenance requirements.

In the foregoing specification, the invention has been described with reference to specific embodiments; however, one of ordinary skill in the art appreciates that various modifications and changes can be made without departing from the scope of the present invention as set forth in the claims below. Accordingly, the specification is to be regarded in an illustrative, rather than a restrictive sense, and all such modifications are intended to be included within the scope of the present invention.

Benefits, other advantages, and solutions to problems have been described above with regard to specific embodiments; however, the benefits, advantages, solutions to problems, and any element(s) that may cause any benefit, advantage, or solution to occur or become more pronounced are not to be construed as a critical, required, or essential feature or element of any or all the claims.

As used herein, the terms “comprises,” “comprising,” “includes,” “including,” “has,” “having,” “at least one of,” or any other variation thereof, are intended to cover a non-exclusive inclusion. For example, a process, method, article, or apparatus that comprises a list of elements is not necessarily limited only to those elements, but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

1. A system comprising:
a trailer comprising a frame or body and one or more wheels coupled thereto for moving the trailer, the trailer having an area for receiving one or more self-propelled and/or self driven energy storage systems;
one or more quick couple/quick release mechanical connectors attached to the trailer so as to hold the self-propelled and/or self driven energy storage system;
a power source joined with the trailer; and
a power coupling module having a quick couple/release electrical connector to releasably connect the power source with the energy storage system.

2. The system of claim 1, wherein the power source comprises a generator that converts mechanical energy to electrical energy wherein the mechanical energy is derived from motion of the trailer.

3. The system of claim 1, further comprising a power coupling module integrated with the trailer, an energy storage module integrated with the trailer, the power coupling module, the energy storage module, and the power source being joined to provide electrical power to a load selected from the group consisting of power tools, light sources, battery packs, batteries, capacitors, and electric vehicles.

4. The system of claim 1, wherein the power source comprises an energy harvesting module to recover energy from deceleration, down-hill driving (potential energy change), and/or regenerative braking of the trailer.

5. The system of claim 1, wherein the power source comprises an energy harvesting module to recover energy thermoelectrically from waste heat and/or piezo-electrically from excess motion.

6. The system of claim 1, wherein the power source comprises:
a power generation module to convert mechanical energy to electrical energy;
a power harvesting module to recover energy from deceleration, down-hill driving (potential energy change), and/or regenerative braking of the trailer; and/or
a power harvesting module to recover energy thermoelectrically from waste heat and/or piezo-electrically from waste motion.

7. The system of claim 1, wherein the power source comprises a power generation module to convert chemical fuel into electrical power.

8. The system of claim 1, wherein the power source comprises a power generation module to convert mechanical energy into chemical fuel.

9. The system of claim 1, wherein the power source comprises a power generation module to convert mechanical energy into compressed gas energy.

10. The system of claim 1, wherein the power source comprises a power generation module to produce hydrogen.

11. The system of claim 1, wherein the power source comprises a power generation module comprising a hydrogen fuel cell and/or a water electrolyzer.

12. The system of claim 1, wherein the power source comprises a power generation module that generates electrical power from compressed air.

13. The system of claim 1, wherein the power source comprises a power generation module that generates electrical power from compressed natural gas.

14. The system of claim 1, wherein the power source comprises a power harvest module to convert mechanical energy into chemical fuel.

15. The system of claim 1, wherein the power source comprises a power harvest module to convert mechanical energy into compressed gas energy.

16-28. (canceled)

29. The system of claim 1, further comprising a control and communication module; a sensor on each wheel coupled to transmit data to the control and communication module to automatically select a mode of operation from the group consisting of providing maximum power to charge the energy storage system, providing less than maximum power to charge the energy storage system, and not charging the energy storage system.

30. The system of claim 29, wherein the area for receiving the one or more self-propelled and/or self driven energy storage systems comprises a track for placement of the one or more energy storage systems.

31. The system of claim 29, wherein the area for receiving one or more self-propelled and/or self driven energy storage systems comprises a track and a mechanical coupling mechanism for forming a releasable quick connect/disconnect with one or more self-propelled and/or self driven energy storage systems; the mechanical coupling mechanism being slidably attached to the track for movable placement of the one or more self-propelled and/or self driven energy storage systems on the track.

32. The system of claim 29, wherein the area for receiving one or more self-propelled and/or self driven energy storage systems comprises a track for placement of the first energy storage module, the track being connected with the power coupling module so that placement of the first energy storage module on the track completes an electrical connection with the power coupling module to provide power to the first energy storage module.

33. The system of claim 29, further comprising a power shutoff switch integrated with the power source and/or the electrical coupling module; the power shutoff switch being operable to terminate power transfer in response to a mechanically activated or a wirelessly activated trigger/signal.

34-51. (canceled)
